(19) United States
(12) Patent Application Publication
(10) Pub. No.: US 2023/0032055 A1
(43) Pub. Date: Feb. 2, 2023

(54) ELECTRON-GAS THERMOELECTRIC SENSOR

(71) Applicant: COMMISSARIAT A L'ENERGIE ATOMIQUE ET AUX ENERGIES ALTERNATIVES, Paris (FR)

(72) Inventors: Guillaume SAVELLI, Grenoble Cedex 09 (FR); Charlotte BRYAN, Grenoble Cedex 09 (FR); Rene ESCOFFIER, Grenoble Cedex 09 (FR); Marc PLISSONNIER, Grenoble Cedex 09 (FR)

(73) Assignee: COMMISSARIAT A L'ENERGIE ATOMIQUE ET AUX ENERGIES ALTERNATIVES, Paris (FR)

(21) Appl. No.: 17/758,720

(22) PCT Filed: Jan. 14, 2021
(86) PCT No.: PCT/EP2021/050734

§ 371 Date: Jul. 13, 2022

(30) Foreign Application Priority Data
Jan. 16, 2020 (FR) FR2000402

(51) Int. Cl. G01K 7/02

(52) U.S. Cl. CPC G01K 7/028

(57) ABSTRACT

A multilayer thermoelectric sensor for generating an electric current under the effect of heating includes a support and a thermocouple borne by the support. The thermocouple includes a first thermoelectric member having at least a portion of a bilayer, the layers of which are made of different materials, and a second thermoelectric member having a p-doped semiconductor material and/or a thermoelectric metal. The thermocouple is configured to generate an electron gas at the interface between the layers of the bilayer when the thermoelectric sensor is heated.

The present invention relates to a multilayer thermoelectric sensor, notably for measuring the temperature of an electronic unit of an electronic component, for example a power transistor. It also relates to an electronic component comprising a power transistor and such a thermoelectric sensor, together with a method of fabrication of the thermoelectric sensor and of the power electronic component.

The electronic units constituting an electronic component, notably a power electronic component, can heat up when they are electrically powered. One example of such a unit is a power transistor, for example based on a material such as gallium nitride (GaN), gallium arsenide (AsGa), or gallium-indium (InGa), which heats up under the effect of the electrical power that it generates. It is therefore advantageous to control the variation over time of the temperature of the transistor in order to avoid overheating of the electronic component containing it. For this purpose, the heat flow and/or the temperature of the transistor may be measured in order to adapt the electrical control of the transistor accordingly.

Currently, resistors that are variable as a function of the temperature, also known as thermistors or “Tsense” resistors, are implemented for measuring the temperature of such transistors. They are for example:
integrated metal thermistors made of platinum which are decoupled from the active region of the component;
thermistors made of resistive materials other than platinum, for example NiCr or TaN, and
external thermistors made of platinum, or silicon diodes, which are disposed outside of the electronic component.

All these thermistors need to be electrically powered by means of a current source. Moreover, the implementation of these resistors requires an additional step during the fabrication of the integrated circuit.

There exists therefore a need for a simple way of measuring the temperature of an electronic unit within an electronic component, and preferably without complicating the fabrication of the electronic component.

The invention meets this need by providing a multilayer thermoelectric sensor, for generating an electrical current under the effect of heating, the thermoelectric sensor comprising a carrier and a thermoelectric couple borne by the carrier and comprising:

a first thermoelectric member comprising at least one portion of a bilayer the layers of which are made of different materials, and

a second thermoelectric member comprising a p-doped semiconductor material and/or a thermoelectric metal,

the thermoelectric couple being configured for generating an electron gas at the interface between the layers of the bilayer during the heating of the thermoelectric sensor.

By generating an electron gas at the interface between the layers composing it under the effect of heating, the bilayer behaves substantially as a n-doped semiconductor thermoelectric material.

Advantageously, the fabrication of such a thermoelectric sensor is straightforward since the electron gas may be generated by means of undoped semiconductor materials. One or more doping steps for the layers of the bilayer may thus be obviated.

Furthermore, the invention relates to an electronic component comprising a thermoelectric sensor according to the invention and an electronic unit disposed on the carrier, the electronic component being configured so that the thermoelectric sensor generates an electrical current under the effect of the heating of the electronic unit.

Thus, by measuring the current and/or the electrical voltage at the terminals of the thermoelectric sensor, the heating and/or the temperature of the electronic unit may be measured without any source of electrical current being needed to power the thermoelectric sensor.

The invention further relates to a device chosen from amongst a power converter, a motor control unit and a microwave power amplifier, the device comprising an electronic component according to the invention.

Lastly, the invention relates to a method of fabrication of a thermoelectric sensor according to the invention, the method comprising the following successive steps for:
a) deposition of a first material onto a substrate comprising the carrier in order to form the lower layer of the bilayer, and deposition of a second material in contact with the lower layer so as to form the upper layer of the bilayer,
b) formation of at least one groove running right through the upper layer across the thickness of the upper layer and extending into the lower layer,
the portion of the bilayer contiguous with the groove and which extends along the groove defining the first thermoelectric member,
c) formation of at least one electrically-insulating coating covering, entirely or in part, the face or faces of the groove,
d) formation of at least one insertion layer at least in part in contact with the electrically-insulating coating and, optionally, p-type doping of the insertion layer in order to form the second thermoelectric member.

The bilayer comprises a lower layer and an upper layer in contact with one another. The lower layer is sandwiched between the carrier and the upper layer.

Preferably, each of the layers of the bilayer are undoped. Thus, the first thermoelectric member behaves substantially as an n-doped semiconductor thermoelectric material, without any doping of the layers of the bilayer being necessary.

Those skilled in the art know how to determine pairs of materials for forming the upper and lower layers, which are capable of generating an electron gas. For this purpose, for example:

the lower layer is of SrTiO₃ and the upper layer is of LaAlO₃, or

the lower layer is of GaAs and the upper layer is of AlGaAs, or

the lower layer is of GaN and the upper layer is of AlGaN.

Preferably, the bilayer consists of a layer of gallium nitride and of a layer of aluminum-gallium nitride.

Preferably, the lower layer is of gallium nitride and the upper layer is of aluminum-gallium nitride.

The lower layer may have thickness in the range between 1 μm and 5 μm, notably between 2 μm and 4 μm.

The upper layer may have a thickness in the range between 10 nm and 50 nm.

Furthermore, the first thermoelectric member may comprise an electron trapping film sandwiched between the layers of the bilayer and in contact with each of the layers of the bilayer.

The electron trapping film allows the quantity of electrons in the electron gas, which is trapped between the energies of the bands of the materials constituting the layers of the bilayer, to be increased. Preferably, the trapping film is made of aluminum nitride.

The electron trapping film is thin. It may have a thickness which is more than ten times thinner than the thinnest of the layers of the bilayer. The electron trapping film may have a thickness of less than 1 nm, for example of around 0.7 nm.

The electron trapping film may be discontinuous or, preferably, continuous. It may extend over the entire interface between the layers of the bilayer.

The second thermoelectric member is made of a p-doped semiconductor material or of a thermoelectric metal.

The p-doped semiconductor thermoelectric material is preferably chosen from amongst gallium nitride, aluminum-gallium nitride, gallium arsenide, gallium-indium, gallium-indium nitride, aluminum nitride, aluminum-indium nitride and their mixtures, p-doped by a dopant element, for example chosen from amongst zinc, mercury, cadmium, magnesium and their mixtures. Preferably, the p-doped thermoelectric material is p-doped gallium nitride or p-doped aluminum-gallium nitride.

Preferably, the second thermoelectric member is made of a thermoelectric metal. A step for doping the second thermoelectric member during the fabrication of the thermoelectric sensor is thus avoided.

The thermoelectric metal may be chosen from amongst titanium, gold, aluminum, platinum and their alloys. For example, the thermoelectric metal is aluminum.

Furthermore, the thermoelectric sensor may comprise at least one layer sandwiched between the lower layer and the carrier. In particular, the thermoelectric sensor may comprise a sensor stack disposed on and in contact with the carrier and comprising, consecutively stacked on top of one another:

a layer of aluminum nitride, for example of thickness equal to 50 nm,

the lower layer of gallium nitride, for example of thickness in the range between 2 μm and 4 μm, and

the upper layer of aluminum-gallium nitride, for example of thickness in the range between 10 nm and 40 nm.

Preferably, the upper layer, and optionally the lower layer, of the bilayer and the second thermoelectric member have first and second regions not superposed on top of one another. At least the upper layer and the second electrical member may thus be disposed side by side on the thermoelectric sensor.

The second thermoelectric member may be superposed onto the lower layer of the bilayer.

Preferably, the second thermoelectric member is accommodated, at least in part, in a groove formed in the bilayer.

Preferably, the groove passes right through the upper layer across the thickness of the bilayer and extends into the lower layer.

In one embodiment, the groove may pass through the bilayer from one side to the other across the thickness of the bilayer.

Preferably, the groove extends longitudinally and emerges onto the two edges opposing one another of the bilayer. Thus, as will become clearly apparent in the following, the groove may separate the upper layer, or even the bilayer into two separate parts. The two separate parts can thus each define two first thermoelectric members electrically isolated from one another, which may be destined to form different thermoelectric couples.

The groove may extend in a curvilinear or, preferably, rectilinear direction.

Furthermore, the groove may have a U-shaped or semi-circular cross-section. The depth of the groove, measured between the face onto which the groove emerges and the bottom of the groove, may be in the range between 10 nm and 150 nm. For example, it is equal to 125 nm. The width of the groove may be in the range between 1500 and 3000 nm and/or the length of the groove may be in the range between 0.5 mm and 2.0 mm, for example equal to 1.0 mm.

The second thermoelectric member may extend over the entire length and, preferably, across the whole width of the groove.

Preferably, the second thermoelectric member takes the form of a strip, preferably rectilinear, whose width is in the range between 1.0 μm and 3.0 μm, for example equal to 2.0 μm and whose length in the range between 0.5 mm and 2.0 mm, for example equal to 1.0 mm. Furthermore, the thickness of the second thermoelectric member may be in the range between 0.5 μm and 1.5 μm, for example equal to 1.0 μm.

Furthermore, the second thermoelectric member may have a thickness greater than the depth of the groove. It may protrude from the face of the upper layer of the bilayer.

For its part, the first thermoelectric member may have a width in the range between 3.0 μm and 5.0 μm, for example equal to 4.0 μm and/or the length of the first thermoelectric member may be in the range between 0.5 mm and 2.0 mm, for example equal to 1.0 mm.

Preferably, viewed in a direction normal to the carrier, the first thermoelectric member and the second thermoelectric member each take the form of a strip, curvilinear or preferably rectilinear. In particular, the ratio of the length of the first thermoelectric member, respectively of the second thermoelectric member, to the width of the first thermoelectric member, respectively of the second thermoelectric member, may be greater than 100, preferably greater than 200, preferably greater than 500.

The first and second thermoelectric members are preferably disposed parallel to one another, a long edge of the first thermoelectric member facing a long edge of the second thermoelectric member. Thus, the thermoelectric couple extends in a longitudinal direction parallel to the longitudinal directions of the first and second thermoelectric members.

Preferably, the first and second thermoelectric members are electrically connected together in at least one electrical connection region and are electrically isolated from one another in at least one electrically-insulating region.

Preferably, the thermoelectric sensor comprises an electrically-insulating coating, disposed between the first thermoelectric member and the second thermoelectric member. The insulating coating electrically isolates the first and second thermoelectric members within the electrically-insulating region.

The electrically-insulating coating may be in contact with the first thermoelectric member and with the second thermoelectric member.

The electrically-insulating coating is made of an electrically-insulating material which may be chosen from within the group formed by Si₃N₄, SiO₂, HfO₂, Al₂O₃ and their mixtures. Preferably, the electrically-insulating material is alumina.

Preferably, the electrically-insulating coating has a thickness in the range between 10 nm and 2000 nm.

The length of the electrically-insulating region, measured in the direction of extension of the second thermoelectric member, may be in the range between 0.5 mm and 2.0 mm.

The electrically-insulating coating may receive, at least partially, or even totally, the face or faces of the groove.

The electrically-insulating region and the electrical connection region may not be joined. The electrically-insulating region may be defined by the face or faces common to the first and second thermoelectric members and electrical connection regions may be defined by other faces of the first and second thermoelectric members. For example, the electrically-insulating region is defined by the face or faces of the groove, and respective electrical connection regions may be respectively defined by the top faces of the first and second thermoelectric members.

As a variant, the electrically-insulating region and the electrical connection region may be joined together. Notably, the electrically-insulating region may comprise a portion of the faces of the first and second thermoelectric members in contact with the electrically-insulating coating and at least one electrical connection region may comprise another portion of said common faces.

Preferably, the electrical connection region is disposed at less than 50 μm, or even at less than 10 μm, from a longitudinal edge of the second thermoelectric member.

The ratio between the length of extension of the electrical connection region to the length of extension of the electrically-insulating region may be in the range between 0.0001 and 0.01, said lengths being measured along the longitudinal direction of the second thermoelectric member.

The electrical connection region may extend over a length in the range between 0.5 μm and 2.5 μm.

Furthermore, in order to provide the electrical connection between the first thermoelectric member and the second thermoelectric member, the thermoelectric sensor may take various forms.

The first and second thermoelectric members may be in contact within the electrical connection region. Preferably, the contact area between the first and second thermoelectric members is defined by a part of a face common to the first and second thermoelectric members.

As a variant, the thermoelectric couple may comprise an electrical connector electrically connecting the first and second thermoelectric members which are at a distance from one another.

In particular, the electrical connector may be an electrically-conducting bridge formed from one or more electrically-conducting layers, notably metal layers, superposed at least partially onto the first thermoelectric member and onto the second thermoelectric member. Preferably, the material forming the electrically-conducting bridge is chosen from amongst copper, silver, lead, gold, aluminum and their alloys, and is preferably aluminum.

The thermoelectric sensor may furthermore comprise an electrically-insulating spacer, for example made of silicon oxide, sandwiched between the electrically-conducting bridge and the first and second thermoelectric members.

The electrically-conducting bridge may connect faces, for example top faces, of the first and second thermoelectric members, which are opposite to the faces covered, preferably entirely, by the electrically-insulating coating.

Preferably, in order to increase the electrical current or the electrical voltage generated when the power transistor heats up, the thermoelectric sensor comprises several thermoelectric couples.

The thermoelectric couples may be electrically connected together in parallel or, preferably, in series.

The first thermoelectric member of one of the thermoelectric couples may be electrically connected, within an electrical interconnection region, with the second thermoelectric member of one of the other thermoelectric couples.

Preferably, the electrical interconnection region between two thermoelectric couples is disposed at a distance from each of the electrical connection regions of the two respective thermoelectric couples. In particular, the distance between the electrical interconnection region and the electrical connection region of at least one, preferably of both, thermoelectric couples, is greater than 100 μm, preferably greater than 200 μm, preferably greater than 500 μm. Preferably, the first thermoelectric member of one of the thermoelectric couples is electrically connected, by means of an interconnection member, with the second thermoelectric member of one of the other thermoelectric couples. The interconnection member is preferably made of metal and electrically connects the first and second thermoelectric members. Preferably, the interconnection member has parts in contact with the top faces of the first and second thermoelectric members and at least one part at a distance from the first and second members. Another spacer made of an electrically-insulating material, for example of silica, may be sandwiched between the other part of the interconnection member and the first and second thermoelectric members.

In the electrical interconnection region, the first thermoelectric member of one of the thermoelectric couples may be in contact with the second thermoelectric member of the other thermoelectric couple. As a variant, the first thermoelectric member of one of the thermoelectric couples and the second thermoelectric member of the other of the thermoelectric couples may be electrically connected via an interconnection member, for example such as described hereinabove.

Furthermore, all or part of the first thermoelectric member of one of the thermoelectric couples may be at a distance from the second thermoelectric member of one of the other thermoelectric couples. In particular, said first thermoelectric member may be separated from the second thermoelectric member of the other thermoelectric couple by the electrically-insulating coating of the other thermoelectric couple.

Preferably, the thermoelectric couples are aligned one next to the other in a direction of alignment which is oblique, preferably perpendicular, to the longitudinal direction of each thermoelectric couple.

The thermoelectric couples may be identical to one another. As a variant, they may differ from one another. For example, they may have different dimensions and/or comprise different electrical means of connection of the first and second thermoelectric members.

In particular, the thermoelectric sensor comprises the regular, preferably periodic, repetition in a direction of alignment of an elementary pattern formed from at least one thermoelectric couple, in particular from two electrically interconnected thermoelectric couples.

In one embodiment, the thermoelectric couples are electrically connected in series. The first thermoelectric member of one of the thermoelectric couples may be at a distance from the first thermoelectric member of each of the other thermoelectric couples and the second thermoelectric member of one of the thermoelectric couples may be at a distance from the second thermoelectric member of each of the other thermoelectric couples. Any short-circuit within the group of thermoelectric couples is thus avoided. Preferably, the first thermoelectric member of one of the thermoelectric couples is electrically connected to the first thermoelectric member of at least one of the adjacent thermoelectric couples, by means of the respective second thermoelectric member of the adjacent thermoelectric couple.

Furthermore, the carrier may be formed from silicon.

It may take the form of a plate having a thickness that may be greater than 0.5 mm, for example 1 mm.

The carrier may be self-supporting, in other words it can deform, and notably bend, without breaking under the effect of its own weight.

Furthermore, as described hereinabove, the invention also relates to an electronic component comprising a thermoelectric sensor according to the invention and an electronic unit disposed on the carrier.

The electronic unit and the thermoelectric sensor are preferably separated from one another, for example by a separation distance in the range between 1 μm and 500 μm. The thermoelectric sensor can thus readily detect an increase in the temperature of the electronic unit, for example of at least 0.1° C.

Preferably, the electronic unit is a multilayer.

Preferably, the electronic unit comprises a base containing a material chosen from amongst gallium nitride, aluminum-gallium nitride, gallium arsenide, gallium-indium, gallium-indium nitride, aluminum nitride, aluminum-indium nitride.

The electronic unit may comprise:
a base layer comprising, or consisting of, the material of the lower layer of the bilayer, and
optionally, an additional layer in contact with the base layer, comprising, or consisting of, the material of the upper layer of the bilayer, the base layer being sandwiched between the carrier and the layer additional.

Preferably, the base layer is composed of gallium nitride and is optionally doped, and the additional layer is composed of aluminum-gallium nitride and is optionally undoped.

Preferably, the lower layer of the bilayer of the thermoelectric sensor and the base layer of the electronic unit are deposited together by the same method of layer deposition, for example by physical vapor deposition or by chemical vapor deposition.

The lower layer and the base layer may be separated. For example, they may be obtained by a method for depositing an initial layer followed by a local ablation in order to separate the initial layer into the lower base layer and the base layer.

The lower layer and the base layer may be connected to one another and form a common layer shared by the thermoelectric sensor and the electronic unit.

The lower layer and the base layer may have an identical composition.

A layer has a “bottom” face toward the carrier and a “top” face opposite to the bottom face.

Preferably, the lower layer and the base layer have respective bottom faces, disposed at the same height of the carrier. They may have identical thicknesses.

The electronic unit may be chosen from amongst a resistor, a capacitor, an inductor, a diode or a transistor, notably a power transistor.

Preferably, the electronic unit is a power transistor.

The power transistor may comprise a multilayer transistor stack. The multilayer transistor stack may comprise, successively:

a layer of aluminum nitride, for example with a thickness equal to 50 nm,

the base layer comprising, for more than 99.9% of its mass, gallium nitride, for example with a thickness in the range between 2 μm and 4 μm, and

the additional layer comprising, for more than 99.9% of its mass, aluminum-gallium nitride, for example with a thickness in the range between 10 nm and 40 nm.

Preferably, the thermoelectric sensor comprises a multilayer sensor stack which has the same succession of layers as the multilayer transistor stack.

Layers of the same rank, respectively within the multilayer transistor stack and the multilayer sensor stack, preferably have the same chemical composition and may have the same thickness.

Advantageously, the thermoelectric sensor and the power transistor may be fabricated by a succession of simultaneous deposition steps so as to form the layers of the same rank of the respective stacks.

Furthermore, the power transistor may be a field effect transistor, referred to as a FET. Preferably, it is of the HEMT type, acronym for “High Electron Mobility Transistor”.

Furthermore, the thermoelectric sensor according to the invention may be fabricated by means of the method according to the invention.

At the step a), the substrate may comprise, or may consist of, the carrier.

The substrate may furthermore comprise a primary layer or a stack of primary layers. For example, the primary layer may be a layer of aluminum nitride, whose thickness may be in the range between 1 nm and 100 nm, for example equal to 50 nm.

The first material and/or the second material may be deposited by means of a technique chosen from amongst the physical vapor deposition techniques, notably using organometallic precursors also known under the acronym “MOCVD” for “Metal Organic Chemical Vapor Deposition”.

Preferably, the first material is gallium nitride and the second material is aluminum-gallium nitride.

Furthermore, the method may comprise the deposition of an electron trapping film, such as described hereinabove, on the first material, then the deposition of the second material onto the electron trapping film.

At the step b), the groove may be formed by lithography and etching of the bilayer, the groove being defined by the area etched into the bilayer.

“Lithography and etching” of a layer or of a stack of layers is understood to mean a technique comprising, successively:

a step for deposition of a mask by lithography, notably by photolithography, on the top face of the layer or of the stack, the mask having at least one full portion and at least one open portion, and

a step for etching, physical or chemical, of the part of the layer or of the stack covered by the open portion of the mask.

Preferably several grooves are formed at the step b), two adjacent grooves being separated by a first adjacent thermoelectric member. In particular, the grooves may be formed in such a manner as to define an array of grooves.

Preferably, the grooves extend in parallel directions. They are preferably formed at a distance from one another in an oblique direction, preferably perpendicular, to their direction of extension. Thus, two consecutive grooves are separated by a first thermoelectric member. Preferably, two adjacent grooves may be separated by a distance in the range between 0.25 μm and 5.0 μm, for example equal to 4.0 μm.

At the step c), the electrically-insulating coating may be formed by depositing an electrically-insulating material into the groove. In particular, the electrically-insulating coating may be formed by implementing the following successive steps for:
i) deposition of an electrically-insulating material on the upper layer of the bilayer so as to form a temporary layer,
ii) formation of a mask by lithography and etching of the temporary layer, the full portion of the mask being at least partially superposed onto the groove, and
iii) stripping of the lithography mask.

The electrically-insulating material may be chosen from amongst Al₂O₃, TiO₂, HfO₂, SiN, SiO₂ and their mixtures. It is preferably alumina.

The electrically-insulating material may be deposited by a technique chosen from between chemical vapor deposition also referred to as CVD, notably plasma-assisted chemical vapor deposition also referred to as PECVD, and atomic layer deposition also referred to as ALD.

At the step ii), the full portions of the lithography mask may cover less than 10% of the first thermoelectric member adjacent to the groove.

According to one variant embodiment, the full portions of the mask may only partially cover the groove. Thus, at the end of step c), at least one face of the groove is partially devoid from the electrically-insulating coating. It may thus define an electrical contact region between the first thermoelectric member and the second thermoelectric member formed at the step d).

According to another variant embodiment, the full portions of the mask may completely cover the face or faces of the groove.

Preferably, according to the variant where several grooves are formed, the method comprises the formation of several electrically-insulating coatings each at least partially covering the face or faces of one of the corresponding grooves. In particular, at the step ii), the mask may comprise several full portions, each being at least partially superposed onto one of the corresponding grooves.

At the step d), an insertion layer is formed which is at least partly in contact with the electrically-insulating coating.

The insertion layer may be formed by depositing a third material into the groove.

In particular, the third material may be deposited onto the electrically-insulating coating and, where relevant, onto the face or faces of the groove defined by the bilayer.

In particular, the insertion layer may be formed by implementing the following successive steps for:
i′) deposition of a third material onto the upper layer of the bilayer and also onto the electrically-insulating coating, so as to form another temporary layer
ii′) formation of another mask by lithography and etching of the other temporary layer, the full portion of the other mask being superposed at least partially, or even completely, onto insulating coating, and
iii′) removal of the other lithography mask.

Preferably, the third material is a thermoelectric metal, for example aluminum.

Preferably, the full portion of the other mask superposed onto the groove, when viewed from above, takes the form of a strip, preferably rectilinear.

As a variant, the third material may be a semiconductor material chosen from amongst gallium nitride, aluminum-gallium nitride, gallium arsenide, gallium-indium, gallium-indium nitride, aluminum nitride, aluminum-indium nitride and their mixtures. Preferably, the third material is gallium nitride or aluminum-gallium nitride. The method then comprises the doping of the insertion layer by means of a dopant element chosen such that the insertion layer is p-doped, for example magnesium.

Thus, the insertion layer defines a second thermoelectric member.

The method may comprise the formation and, optionally the doping, of several insertion layers, each contained in one of the corresponding grooves.

Thus, the insertion layers define, with adjacent regions on either side of the bilayer, several thermoelectric couples.

In particular, at the step ii′), the other mask may comprise several full portions, each being at least partially, or even completely, superposed onto one of the corresponding grooves.

Preferably, the insertion layers are formed at a distance from one another. In particular, the insertion layers may form an array, preferably substantially homothetic to the array of grooves, two consecutive insertion layers being separated by a portion of the bilayer.

Thus, at the end of step d), the thermoelectric sensor may comprise a plurality of first and second thermoelectric members which, preferably, are disposed in alternation one next to another.

Furthermore, according to the variant where the electrically-insulating coating formed at the end of step c) only partially covers the face or faces of the groove, the method may comprise the deposition of the third material in contact with the bilayer in the portion of the groove not covered by the electrically-insulating coating. Thus, at the end of step d), the first and second thermoelectric members are in contact with one another over a portion of their length, and are electrically connected. They are furthermore electrically isolated from one another by the electrically-insulating coating in the portion where the second thermoelectric member covers the electrically-insulating coating. A thermoelectric couple of the thermoelectric sensor is thus formed.

Furthermore, in the variant where the electrically-insulating coating formed at the end of step c) completely covers the face or faces of the groove, the method preferably comprises a step for formation of an electrical connector electrically connecting the first and second thermoelectric members. A thermoelectric couple of the thermoelectric sensor is thus formed.

More specifically, the method may comprise the formation of a spacer, made of an electrically-insulating material, for example silica, superposed onto the first and second thermoelectric members, followed by the formation of an electrically-conducting bridge electrically connecting the first and second thermoelectric members and being superposed onto the spacer.

In the variant where several first and second thermoelectric members are defined, the method may comprise the formation of several electrically-conducting bridges connecting the corresponding first and second thermoelectric members. A plurality of thermoelectric couples are thus formed.

In particular, the electrically-conducting bridge may be formed on the respective top faces of the first and second thermoelectric members.

Furthermore, the method preferably comprises the formation of at least one interconnection member in order to electrically connect two thermoelectric couples.

More specifically, the method may comprise the formation of another spacer, formed from an electrically-insulating material, for example silica, superposed onto the first thermoelectric member of one of the thermoelectric couples and onto the second thermoelectric member of the other thermoelectric couple, followed by the formation of the interconnection member which is superposed onto the other spacer, and which electrically connects the first thermoelectric member of one of the thermoelectric couples to the second thermoelectric member of the other thermoelectric couple. An electrical interconnection between the thermoelectric couples is thus formed.

As a variant, at the step d), a portion of the groove destined to form the second thermoelectric member of a thermoelectric couple may be devoid of a coating and at the step e), the insertion layer is deposited in contact with the thermoelectric member of the adjacent thermoelectric couple.

Furthermore, the method may comprise, in conjunction with the formation of the electrically-insulating layer of the thermoelectric sensor, the formation of an electrically-insulating layer of the transistor which may be made of the same material as the electrically-insulating layer of the thermoelectric sensor.

Furthermore, the method may comprise the fabrication of the electronic unit, preferably of a power transistor, of an electronic component according to the invention.

Notably, the method may comprise, preferably in conjunction when the formation of the lower layer of the thermoelectric sensor, the deposition of the first material for forming the base layer of the electronic unit.

The base layer and the lower layer may be contiguous and form a monolithic assembly. As a variant, the method may comprise the deposition of the first material for forming a primary layer, then the ablation of a part of the primary layer for separating the primary layer into two separate parts, respectively defining the base layer and the lower layer.

The ablation of the preliminary layer may be carried out by lithography and etching.

The thickness of the base layer and the thickness of the lower layer are preferably equal, for example in the range between 2 μm and 4 μm.

Preferably, the base layer and the lower layer have respective bottom faces, disposed at the same height of the carrier. They may have identical thicknesses.

The method may furthermore comprise the doping of the base layer. The doping may be implemented by doping in-situ during the growth or by ion implantation of a dopant element through the top face of the base layer.

Furthermore, the method may comprise, preferably in conjunction with the formation of the upper layer of the bilayer of the thermoelectric sensor, the deposition of the second material for forming the additional layer of the electronic unit.

The method may comprise the doping of the additional layer.

The additional layer of the thermoelectric sensor and the additional layer of the transistor may have bottom faces disposed at the same height with respect to the carrier.

The invention will be better understood upon reading the detailed description that follows and from the examples and by means of the appended drawings, in which:

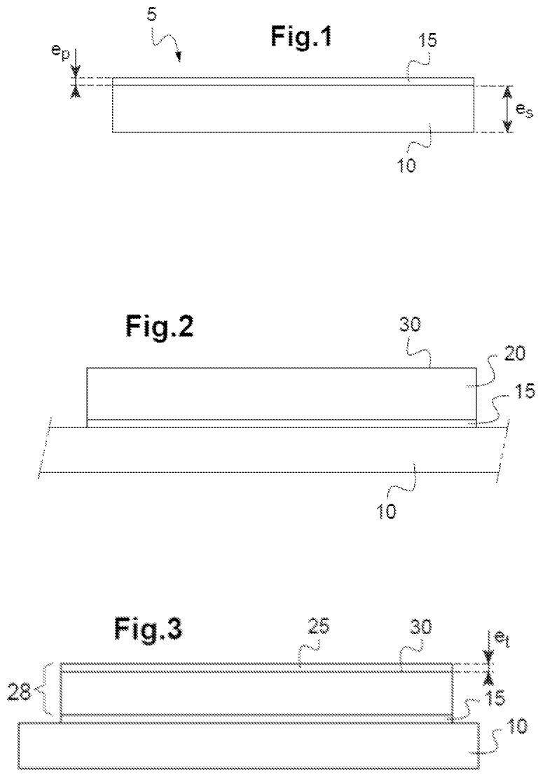

FIG. 1 illustrates, in a transverse cross-sectional view, a step of the method of fabrication of a thermoelectric sensor according to the invention according to a first exemplary embodiment,

FIG. 2 illustrates, in a transverse cross-sectional view, another step of the method according to the first exemplary embodiment,

FIG. 3 illustrates, in a transverse cross-sectional view, another step of the method according to the first exemplary embodiment,

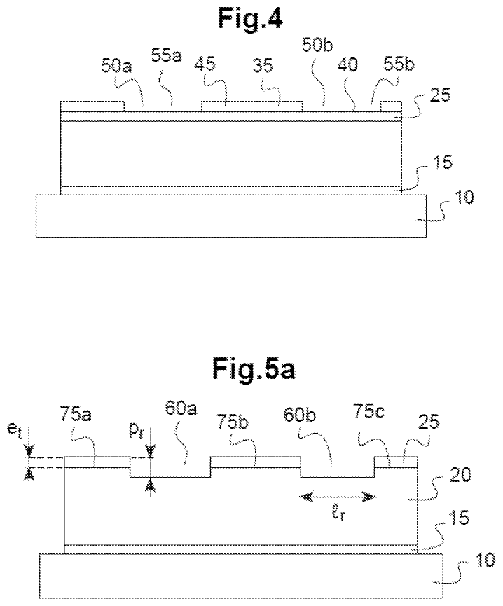

FIG. 4 illustrates, in a transverse cross-sectional view, another step of the method according to the first exemplary embodiment,

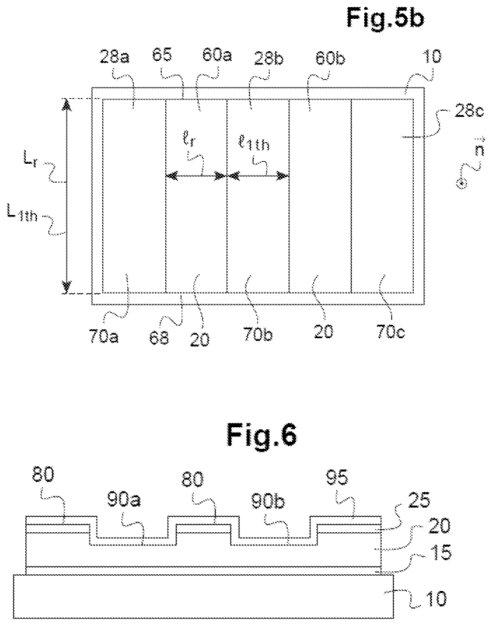

FIG. 5a illustrates, in a transverse cross-sectional view, another step of the method according to the first exemplary embodiment,

FIG. 5b illustrates, in a top view, the step of the method illustrated in FIG. 5a,

FIG. 6 illustrates, in a transverse cross-sectional view, another step of the method according to the first exemplary embodiment,

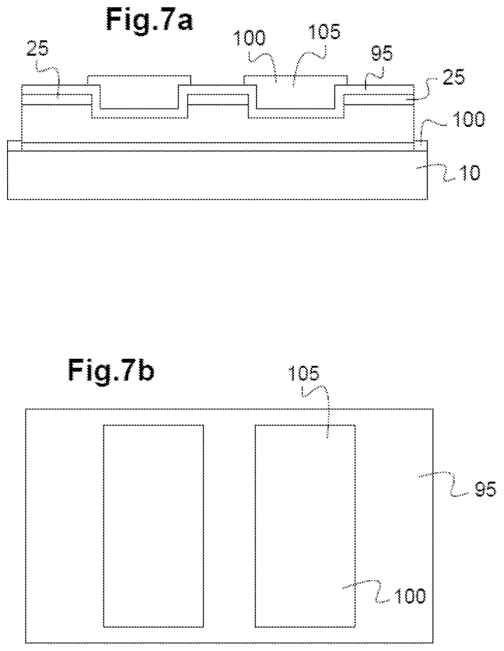

FIG. 7a illustrates, in a transverse cross-sectional view, another step of the method according to the first exemplary embodiment,

FIG. 7b illustrates, in a top view, the step of the method illustrated in FIG. 7a,

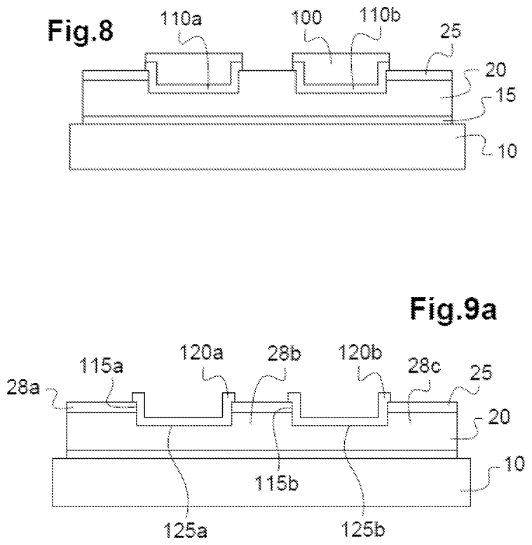

FIG. 8 illustrates, in a transverse cross-sectional view, another step of the method according to the first exemplary embodiment,

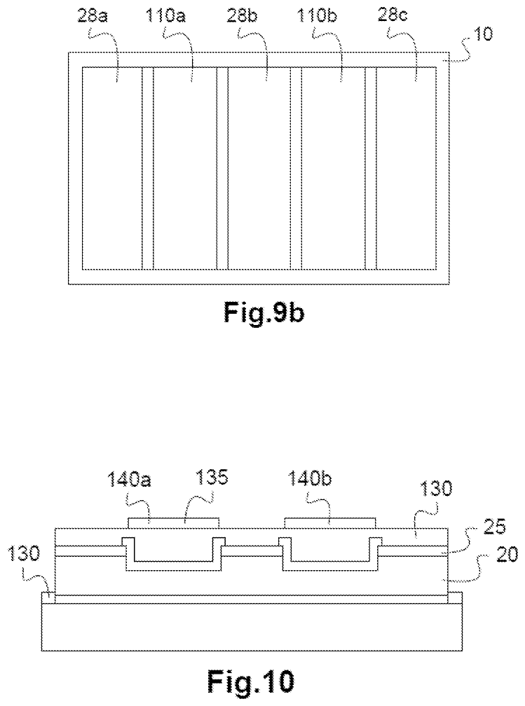

FIG. 9a illustrates, in a transverse cross-sectional view, another step of the method according to the first exemplary embodiment,

FIG. 9b illustrates, in a top view, the step of the method illustrated in FIG. 9a,

FIG. 10 illustrates, in a transverse cross-sectional view, another step of the method according to the first exemplary embodiment,

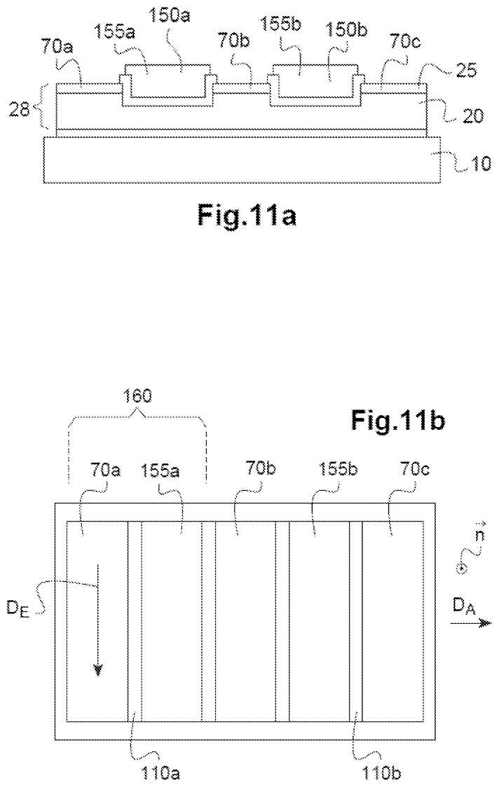

FIG. 11a illustrates, in a transverse cross-sectional view, another step of the method according to the first exemplary embodiment,

FIG. 11b illustrates, in a top view, the step of the method illustrated in FIG. 11a,

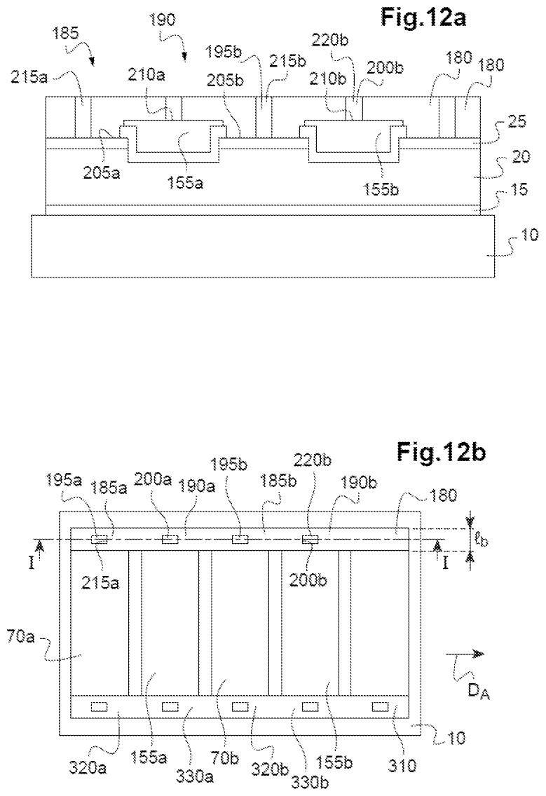

FIG. 12a illustrates, in a transverse cross-sectional view according to the cross-sectional plane (II), another step of the method according to the first exemplary embodiment,

FIG. 12b illustrates, in a top view, the step of the method illustrated in FIG. 12a,

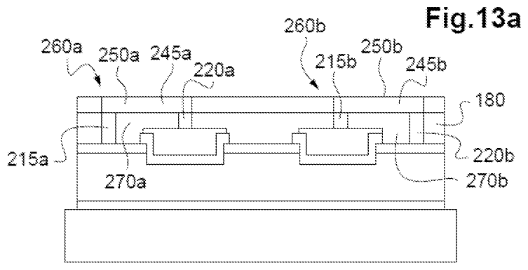

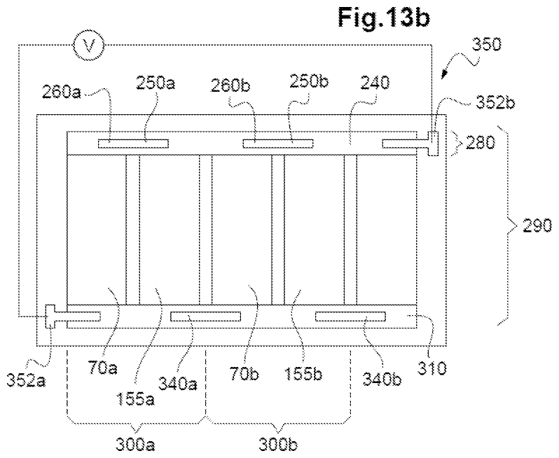

FIG. 13a illustrates, in a transverse cross-sectional view, another step of the method according to the first exemplary embodiment,

FIG. 13b illustrates, in a top view, the step of the method illustrated in FIG. 13a, and

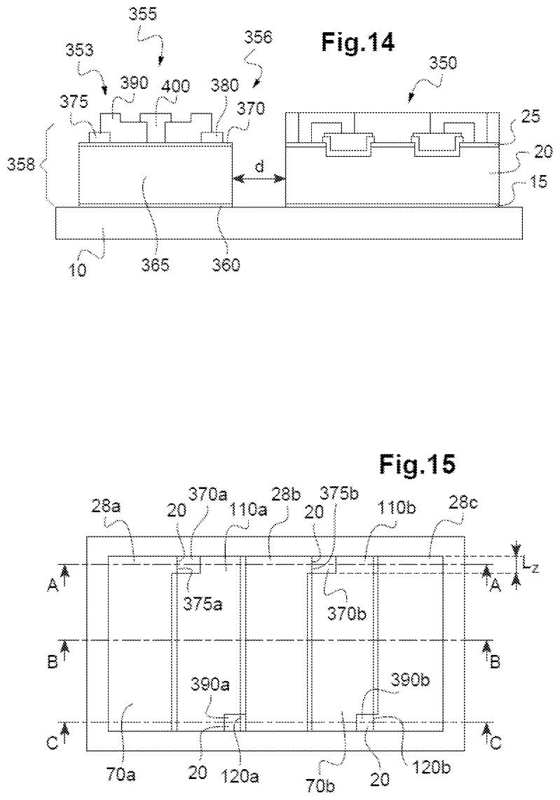

FIG. 14 illustrates, in a transverse cross-sectional view, an electronic component according to the invention fabricated according to the first exemplary embodiment,

FIG. 15 illustrates, in a top view, a step of the method according to a second exemplary embodiment,

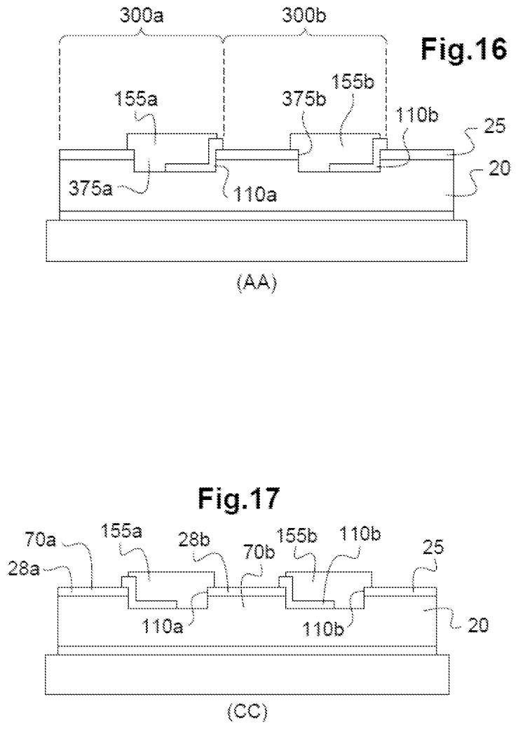

FIG. 16 illustrates, in a transverse cross-sectional view according to the cross-sectional plane (AA), the step of the method illustrated in FIG. 15, and

FIG. 17 illustrates, in a transverse cross-sectional view according to the cross-sectional plane (CC), the step of the method illustrated in FIG. 15.

For the sake of clarity of the drawings, the proportions of the various elements constituting the electronic components illustrated are not shown to scale.

### EXAMPLE 1

FIGS. 1 to 14 show a first exemplary embodiment of the method according to the invention for fabricating one example of a thermoelectric sensor according to the invention.

At the step a), as illustrated in FIG. 1, a substrate 5 is provided which comprises a carrier 10 made of silicon and a primary layer 15 of aluminum nitride which covers the substrate. For example, the thickness of the carrier eₛ is equal to 1.0 mm and the thickness of the primary layer eₚ of aluminum nitride is equal to 50 nm.

A layer 20 of gallium nitride is subsequently formed, for example by physical vapor deposition or by chemical vapor deposition, in contact with the primary layer of aluminum nitride.

A layer 25 of aluminum-gallium nitride is subsequently deposited in contact with the top face 30 of the layer of gallium nitride, as illustrated in FIG. 3, for example by physical vapor deposition or by chemical vapor deposition. The layer 25 of aluminum-gallium nitride preferably covers the top face of the layer of gallium nitride entirely. As a variant, prior to the deposition of the layer 25 of aluminum-gallium nitride, a thin electron trapping film, with a thickness for example of 0.7 nm and made of aluminum nitride, may be deposited onto the layer 20 of gallium nitride. The trapping layer is thus sandwiched between the layer 20 of gallium nitride and the layer 25 of aluminum-gallium nitride.

A bilayer 28 is thus formed, comprising a lower layer 20 of gallium nitride and an upper layer 25 of aluminum-gallium nitride.

As is illustrated in FIG. 4, at the step b), grooves are formed in the bilayer. A mask 35 is formed by photolithography on the top face 40 of the upper layer of aluminum nitride. It comprises at least one full portion 45, consisting for example of a thermosensitive resin, and recesses 50a-b being superposed onto portions 55a-b of the top face 40 of the upper layer of aluminum nitride.

The upper layer of aluminum-gallium nitride and the lower layer of gallium nitride are subsequently etched in the portions 55a-b not covered by the full portions of the mask. The etching conditions are adapted in such a manner that the portions 55a-b of the upper layer are entirely removed and that gallium nitride is removed from the portions of the lower layer superposed onto the portions 55a-b. The mask is subsequently removed by stripping. As illustrated in FIGS. 5a and 5b, grooves 60a-b are thus formed, whose respective depths pr are greater than the thickness et of the upper layer 25. The grooves each take the form of a strip, viewed in a direction normal n to the carrier, which extends over the entire length of the lower layer between two of its edges 65, 68 opposite to one another.

Thus, first thermoelectric members 70a-c of thermoelectric couples under formation are created, which respectively comprise parts 28a, 28b and 28c of the bilayer 28.

They each take, viewed in a direction normal n to the carrier, the form of a strip, and extend parallel to the adjacent grooves 60a-b.

The first thermoelectric members 70a-c are thus at a distance and electrically isolated from one another, the grooves having depths pᵣ greater than the thickness eₜ of the upper layer, and extending from one side to the other between the edges 65 and 68. Thus, the interfaces 75a-c between the lower layer and the upper layer of each respective portion 28a-c of the bilayer 28, on which an electron gas can form and move, are electrically insulated from one another.

In the example illustrated, each groove has a length Lᵣ of 1.0 mm, a width lᵣ of 2.06 μm and a depth pᵣ of around 125 nm and each of the first thermoelectric members has a length L₁ₜₕ of 1.0 mm, identical to the length of a groove, a width l₁ₜₕ of 4.0 μm and a thickness, corresponding to the thickness of the doped portion 45, equal to 25 nm.

At the step c), an electrically-insulating coating is formed. An electrically-insulating material may be deposited, as illustrated in FIG. 6, on the top face of the upper layer 25 and on the respective bottom faces 90a-b of the grooves which are defined by the lower layer 20 of gallium nitride. A temporary layer 95 is thus formed. The electrically-insulating material is for example alumina and may be deposited by atomic layer deposition (ALD) or by chemical vapor deposition (CVD).

A mask 100 is subsequently generated by photolithography, the full portions 105 of the mask being totally superposed onto the groove, as illustrated in FIGS. 7a and 7b. The temporary layer is subsequently etched in its part or parts not covered by the full portions of the mask, as illustrated in FIG. 8. After stripping the full portions of the mask, electrically-insulating coatings 110a-b are formed, each entirely covering the lateral faces 115a-b,120a-b and the bottom face 125a-b of each of the grooves. Thus, each electrically-insulating coating extends across the whole width and over the entire length of the groove that it covers.

At the step d), in the example illustrated, a third material is deposited, for example a thermoelectric metal, in particular aluminum, on the top face of the bilayer and on the electrically-insulating coating, in such a manner as to form another temporary layer 130. Another mask 135 is subsequently formed by photolithography, whose full portions 140a-b completely cover the groove, as illustrated in FIG. 10.

After etching the other temporary layer and stripping the other mask, insertion layers 150a-b are formed, each of which entirely fills a corresponding groove. Each insertion layer protrudes from the bilayer 28. Furthermore, since the insertion layers are formed from a thermoelectric material, they each define second thermoelectric members 155a-b designed to form, with first corresponding thermoelectric members, thermoelectric couples 300a-b.

Each second thermoelectric member is thus contiguous with a first thermoelectric member. The electrically-insulating coating 110a-b forms a barrier between a first thermoelectric member and a second adjacent thermoelectric member, which are thus electrically isolated from one another, as illustrated in FIGS. 11a and 11b.

Furthermore, when observed in the direction n normal to the carrier, the first and second thermoelectric members each extend in directions of extension D_{E} parallel to one another, and are aligned side by side in alternation in a direction of alignment D_{A} perpendicular to the direction of extension D_{E}. Two first and second adjacent thermoelectric members thus form a pattern 160 which is regularly repeated in the direction of alignment D_{A}.

In one variant not illustrated, the third material may be a semiconductor and the method may comprise the doping of the insertion layer in order to endow it with thermo-electrical properties. In the example illustrated, the insertion layer may be of gallium nitride or of aluminum-gallium nitride and may be p-doped by implanting magnesium.

As described hereinabove, in the example illustrated, at the end of step d), the first thermoelectric members are electrically isolated from the second thermoelectric members by means of the electrically-insulating coating 110a-b. In order to form thermoelectric couples capable of generating a Seebeck effect, the method implemented in the example 1 comprises the deposition of a first layer of silica 180 which covers both the longitudinal end parts 185a-b, 190a-b of the first thermoelectric members and of the second thermoelectric members, respectively. As illustrated in FIGS. 12a and 12b, the first layer of silica extends from one side to the other over the upper layer 25 and over the insertion layers, in the direction of alignment D_{A}. Viewed in the direction normal to the carrier, the first layer of silica thus takes the form of a rectilinear strip whose width lb is for example equal to 5.5 μm. Furthermore, the first layer of silica comprises first 195a-b and second 200a-b windows passing right through its thickness and which emerge onto the top face 205a-b of the first thermoelectric member and onto the top face 210a-b of the second thermoelectric member, respectively. Furthermore, the method comprises the formation of first 215a-b and second 220a-b electrically-conducting bump contacts, for example made of metal, and in particular of aluminum, which are accommodated within the windows. The windows, together with the electrically-conducting bump contacts, may be formed successively by a technique of lithography and etching such as described elsewhere in the present description.

Lastly, the method implemented in the example 1 comprises, as illustrated in FIGS. 13a and 13b, the formation of a second layer of silica 240 which is entirely superposed onto the first layer of silica 180 and vice versa. The second layer comprises another window 245a-b which passes right through its thickness and which emerges onto the first 220a-b and second 225 a-b electrically-conducting bump contacts. The other window is furthermore superposed onto the first layer of silica 180 and onto a first thermoelectric member 70a-b and onto a second adjacent thermoelectric member. An electrically-conducting strip 250a-b, for example of aluminum, is accommodated within the window and is in contact with the first and second electrically-conducting bump contacts. Thus, the electrically-conducting bump contacts and strip define an electrically-conducting bridge 260a-b which connects adjacent first 70a-b and second 155a-b thermoelectric members. Furthermore, the portion of the first layer of silica sandwiched between the electrically-conducting bridge and the thermoelectric members is an electrically-insulating spacer 270a-b.

The first and second thermoelectric members are thus electrically connected within an electrical connection region 280 extending over the longitudinal end portion over a length less than the width lb of the silica strip, and are electrically isolated from one another over an electrically-insulating region 290 which extends over the length of the groove. Thermoelectric couples 300a-b are thus created, which each comprises the first 70a-b and second 155a-b thermoelectric members respectively connected via the electrically-conducting bridge 260a-b, which under the effect of the heating of the transistor is capable of generating an electrical current by the Seebeck effect.

In order to increase the voltage generated by the sensor, the thermoelectric couples may be interconnected together in series. In conjunction with the formation of the first layer of silica 180, the method comprises the formation of another layer of silica 310 which covers the longitudinal end parts 320a-b, 330a-b of the first thermoelectric members and of the second thermoelectric members, respectively, opposite to the first layer of silica 180. Interconnection members of 340a-b connecting the second thermoelectric member, for example 155a of a thermoelectric couple, for example 300a, to the first thermoelectric member, for example 70b, of an adjacent thermoelectric couple, for example 300b, are formed according to a method identical to that described hereinabove for generating the electrically-conducting bridges.

A thermoelectric sensor 350, formed from thermoelectric couples electrically connected in series is thus obtained by means of the method implemented in the example 1.

It may be connected to a voltmeter or to an ammeter, by the means of connection lugs 352a-b deposited onto the carrier and to which it is connected, for measuring the electrical voltage or the electrical current respectively generated by an electronic unit 353, disposed on the carrier nearby, as illustrated in FIG. 14. For example, the separation distance d separating the electronic unit and the thermoelectric sensor may be in the range between 1 μm and 500 μm.

FIG. 14 illustrates an electronic component 356 comprising a thermoelectric sensor and an electronic unit 353 disposed on the carrier.

The electronic unit is for example a power transistor 355. It comprises, as the thermoelectric sensor 350, a stack 358 formed, consecutively and in contact one on top of the other, from:
a primary layer 360 of aluminum nitride,
a base layer 365 of gallium nitride, and
an additional layer 370 of aluminum-gallium nitride.

The primary layers 15 and 360 preferably have the same thickness, the base layer 365 and lower layer 20 preferably have the same thickness and the additional layer 370 and upper layer 25 preferably have the same thickness.

The power transistor further comprises, on and in contact with the additional layer, a drain layer 375, a metal source layer 380, a layer for isolating the transistor 390 and a gate layer 400.

Preferably, the primary layer of the transistor, the base layer 365 and the additional layer are respectively formed during the same deposition steps as the primary layer, the lower layer and the upper layer of the thermoelectric sensor, respectively.

In other words, the method comprises the formation of the primary layer of the transistor, of the base layer and of the additional layer in conjunction with the deposition of the primary layer, the lower layer and the upper layer of the thermoelectric sensor, respectively.

Furthermore, the drain layer and the metal layer are preferably made of metal. They may be formed during the operation for deposition of the third material of the insertion layer of the thermoelectric sensor.

### EXAMPLE 2

The thermoelectric sensor of the electronic component in the example 2, according to the invention, differs from that illustrated in the example 1 in that the first and second thermoelectric members of a thermoelectric couple are in direct contact with each other within an electrical connection region 370.

The thermoelectric sensor may be fabricated by implementing the steps a) and b) described hereinabove in order to form a groove.

As illustrated in FIG. 15, the method of fabrication differs from that implemented in the example 1 in that an electrically-insulating coating 110a-b is formed which partially covers only the faces of the groove. In order to form such a coating, a mask is deposited on the temporary layer 95, which is not superposed onto a portion of the groove in a longitudinal end portion 370a-b of the groove. In particular, in said longitudinal end portion, the electrically-insulating coating 110a covers the part of the groove contiguous with a portion 28b of the bilayer 28 destined to form a first thermoelectric member 70b of another adjacent thermoelectric couple. The formation of a short-circuit within the thermoelectric sensor is thus avoided.

The method subsequently comprises the formation of an insertion layer as described in the example 1, which entirely fills the volume of the groove. As illustrated in FIG. 16, the second thermoelectric member 155a-b thus formed is, in the end portion of the groove, in direct contact with an adjacent first thermoelectric member within an electrical connection region 375a-b and electrically isolated from the other adjacent first thermoelectric member. The electrical contact region may notably extend over a distance L_{z}, measured along the length of the groove, of less than 10 μm. Furthermore, in the electrically-insulating region 380a-b, where the electrically-insulating coating completely covers the faces of the groove, the first and second thermoelectric members are at a distance from one another and electrically isolated, as already illustrated in FIG. 11a.

The method according to the second example is thus particularly simple to implement. The thermoelectric sensor may be fabricated with a limited number of layers to be deposited.

Furthermore, in order to interconnect two adjacent thermoelectric couples, the electrically-insulating coating is not superposed, in the opposite end portion 390a-b of the groove, onto the face of the groove 120a-b contiguous with the portion of the bilayer destined to form a first thermoelectric member of another thermoelectric couple. Thus, in the electrical interconnection region as illustrated in FIG. 17, the second thermoelectric member 155a of a thermoelectric couple 300a is in direct contact with the first thermoelectric member 70b of the adjacent thermoelectric couple 300b. The adjacent thermoelectric couples are thus connected in series.

1. A multilayer thermoelectric sensor for generating an electrical current under an effect of heating, the thermoelectric sensor comprising:
a carrier, and
a thermoelectric couple borne by the carrier and comprising:
a first thermoelectric member comprising at least one portion of a bilayer whose layers are of different materials, the layers of the bilayer each being undoped, and
a second thermoelectric member comprising a p-doped semiconductor material and/or a thermoelectric metal,
the thermoelectric couple being configured to generate an electron gas at an interface between the layers of the bilayer during the heating of the thermoelectric sensor.

2. The thermoelectric sensor as claimed in claim 1, the bilayer consisting of a layer of gallium nitride and of a layer of aluminum-gallium nitride.

3. The thermoelectric sensor as claimed in claim 1, the bilayer consisting of an upper layer and of a lower layer sandwiched between the carrier and the upper layer, the lower layer being gallium nitride and the upper layer being aluminum-gallium nitride.

4. The thermoelectric sensor as claimed in claim 3, the upper layer of the bilayer and the second thermoelectric member having first and second regions not superposed onto one another.

5. The thermoelectric sensor as claimed in claim 1, the second thermoelectric member being accommodated, at least in part, within a groove formed in the bilayer.

6. The thermoelectric sensor as claimed in claim 5, the bilayer consisting of an upper layer and of a lower layer sandwiched between the carrier and the upper layer, the groove passing through the upper layer across a thickness of the bilayer and extending into the lower layer.

7. The thermoelectric sensor as claimed in claim 6, the groove passing through the bilayer across the thickness of the bilayer.

8. The thermoelectric sensor as claimed in claim 1, the thermoelectric sensor comprising an electrically-insulating coating of an electrically-insulating material disposed between the first thermoelectric member and the second thermoelectric member.

9. The thermoelectric sensor as claimed in claim 1, the first and second thermoelectric members being in contact within an electrical connection region.

10. The thermoelectric sensor as claimed in claim 1, the thermoelectric couple comprising an electrical connector electrically connecting the first and second thermoelectric members which are at a distance from one another.

11. An electronic component comprising a thermoelectric sensor as claimed in claim 1 and an electronic unit disposed on the carrier, the electronic component being configured such that the thermoelectric sensor generates an electrical current under the effect of the heating of the electronic unit.

12. The electronic component as claimed in claim 11, the electronic unit comprising a base layer containing a material chosen from amongst gallium nitride, aluminum-gallium nitride, gallium arsenide, gallium-indium, gallium-indium nitride, aluminum nitride, and aluminum-indium nitride.

13. The electronic component as claimed in claim 11, the electronic unit comprising:
a base layer comprising the material of the lower layer of the bilayer.

14. The electronic component as claimed in claim 13, the electronic unit being a power transistor in which the base layer is gallium nitride and is optionally doped.

15. A device chosen from amongst a power converter, a motor control unit, a microwave power amplifier, the device comprising an electronic component as claimed in claim 11.

16. The thermoelectric sensor as claimed in claim 4, the lower layer of the bilayer and the second thermoelectric member having first and second regions not superposed onto one another.

17. The thermoelectric sensor as claimed in claim 8, wherein the electrically-insulating coating comprises alumina.

18. The electronic component as claimed in claim 13, comprising an additional layer in contact with the base layer comprising the material of the upper layer of the bilayer, the base layer being sandwiched between the carrier and the additional layer.

19. The electronic component as claimed in claim 18, the additional layer is aluminum gallium nitride and is optionally undoped.
